(19) United States
(12) Patent Application Publication
(10) Pub. No.: US 2007/0013456 A1
(43) Pub. Date: Jan. 18, 2007

(54) VOLTAGE CONTROLLED OSCILLATOR HAVING AUTOMATIC AMPLITUDE CONTROL FUNCTION

(75) Inventors: SOO WOONG LEE, KYUNGKI-DO (KR); YOO HWAN KIM, KYUNGKI-DO (KR); JIN TAEK LEE, KYUNGKI-DO (KR); SUNG CHEOL SHIN, SEOUL (KR); YO SUB MOON, KYUNGKI-DO (KR); KI SUNG KWON, SEOUL (KR)

Correspondence Address: LOWE HAUPTMAN BERNER, LLP, 1700 DIAGONAL ROAD, SUITE 300, ALEXANDRIA, VA, 22314, US

(73) Assignee: SAMSUNG ELECTRO-MECHANICS CO., LTD., KYUNGKI-DO (KR)

(21) Appl. No.: 11/456,525

(22) Filed: Jul. 10, 2006

(30) Foreign Application Priority Data
Jul. 12, 2005 (KR) 10-2005-62471

(51) Int. Cl. H03L 5/00

(52) U.S. Cl. 331/182

(57) ABSTRACT

In a voltage controlled oscillator, a voltage controlled oscillating part includes a resonance circuit, a differential amplifying circuit and an active load. The resonance circuit generates a resonance signal. The differential amplifying circuit feeds back the resonance signal from the resonance circuit and outputs two oscillation signals having a phase difference of 180°. The active load controls gain of the oscillation signals generated in the differential amplifying circuit. Further, an automatic amplitude controlling part converts the oscillation signals into a direct voltage and compares the direct voltage with a preset reference voltage to output a control voltage for determining a resistance value of the active load. The invention effectively adjusts amplitude of the oscillation signals outputted and reduces phase noise resulting from noise components induced by current source in case of switching of the differential amplitude circuit.

### CLAIM OF PRIORITY

This application claims the benefit of Korean Patent Application No. 2005-62471 filed on Jul. 12, 2005 in the Korean Intellectual Property Office, the disclosure of which is incorporated herein by reference.

### BACKGROUND OF THE INVENTION

1. Field of the Invention

The present invention relates to a voltage controlled oscillator having an automatic amplitude control function, more particularly, which employs an active load in place of a current source to adjust gain and thus eliminate phase noises induced by the current source, thereby exhibiting superior properties.

2. Description of the Related Art

Recently wireless devices have been utilized in a variety of wireless application services such as a digital multimedia broadcasting, which are under active developments. The wireless devices adopt a local oscillation circuit to convert a reception signal into a demodulatable low frequency signal, and a transmission signal into a high frequency signal. The local oscillation circuit needs to be wide in an oscillation frequency, and low in phase noises in the vicinity of the oscillation frequency. Especially, unlike an analogue broadcasting, the digital broadcasting does not allow images to be outputted at a signal below a threshold, which can be judged by phase noises in a frequency region. Also, unlike the analogue broadcasting reception system, the digital broadcasting reception system requires high phase noise properties.

Such phase noises are greatly affected by performance of the reception system, particularly the voltage controlled oscillator (VCO). Therefore, in order to minimize phase noises of the entire reception system, it is imperative to minimize phase noises caused by the voltage controlled oscillator.

FIG. 1 is a circuit diagram illustrating a conventional voltage controlled oscillator having an automatic amplitude control (ACC) function. Referring to FIG. 1, the conventional voltage controlled oscillator having the ACC function largely includes a voltage controlled oscillating part 100 and an automatic amplitude controlling part 200.

The voltage controlled oscillating part 100 includes a resonance circuit 110, a differential amplifying circuit 120 and a current source Is. The resonance circuit 110 includes an inductor L connected between two output terminals out1 and out2, and two variable capacitors C1 and C2 serially connected to each other and connected between the output terminals out1 and out2. The differential amplifying circuit 120 includes two transistors N1 and N2 each having a gain connected to a drain and the drain connected to each of the output terminals. Also the current source Is connects sources of the transistor N1 and N2 t a ground. The conventional voltage controlled oscillator employs negative resistance properties of a positive feedback circuit equipped with the transistors N1 and N2. A control voltage V_{ctl} is applied between the variable capacitors C1 and C2 to control capacitance thereof, consequently determining a resonance frequency. A resonance signal from the resonance circuit 110 is inputted to each of the gates of the transistors N1 and N2, thereby producing an oscillation signal having a phase difference of 180° in the output terminals out1 and out2.

In addition, the automatic amplitude controlling part 200 includes a peak detector 210, a low band pass filter 220 and a comparator 240. The peak detector 210 receives two oscillation signals outputted from the output terminals out1 and out2 of the voltage control circuit 110 and detects respective peaks thereof to rectify the oscillation signals. The low band pass filter 220 receives the rectified signals from the peak detector 210 to convert into a direct voltage. Also, a comparator 240 compares the direct voltage outputted from the low band pass filter 220 with a preset reference voltage Vref to output the comparison result.

To control an output level (amplitude) of the voltage controlled oscillator, the conventional voltage controlled oscillator having the ACC function adjusts trans-conductance gₘ of the current source Is of the voltage controlled oscillating part 100 based on an output value from the comparator. That is, if the output direct voltage of the low band pass filter 220 is smaller than the reference voltage Vref, the trans-conductance gₘ is raised to increase gain, thereby elevating the output level of the voltage controlled oscillator. If the output direct current voltage of the low band pass filter 220 is bigger than the reference voltage Vref, the trans-conductance gₘ is reduced to decrease gain, thereby diminishing the output level of the voltage controlled oscillator.

However, the conventional voltage control oscillator having the ACC function disadvantageously experiences increase in phase noises due to noises stemming from the current source Is and various noises transferred from the current source Is in case of switching of the transistors N1 and N2.

Further, a voltage controlled oscillator may be configured without employing the current source to prevent increase in phase noises resulting from the current source Is. But disadvantageously such a voltage controlled oscillator cannot adopt the conventional automatic amplitude controlling part for controlling gain via the trans-conductance of the current source.

### SUMMARY OF THE INVENTION

The present invention has been made to solve the foregoing problems of the prior art and therefore an object according to certain embodiments of the present invention is to provide a voltage controlled oscillator having an automatic amplitude control function which controls gain through adjustment in a resistance value of a load, not through control of trans-conductance as in the prior art, by adopting an active load in place of a current source employed in a conventional voltage controlled oscillator.

According to an aspect of the invention for realizing the object, there is provided a voltage controlled oscillator having an automatic amplitude control function, comprising: a voltage controlled oscillating part including a resonance circuit for generating a resonance signal with a resonance frequency determined by a control voltage, a differential amplifying circuit for feeding back the resonance signal from the resonance circuit and generating two oscillation signals having a phase difference of 180° to output to two output terminals, and an active load for controlling gain of the oscillation signals generated in the differential amplifying circuit; an automatic amplitude controlling part including a peak detector for receiving the oscillation signals and detecting respective peaks thereof to rectify the oscillation signals, a low band pass filter for receiving the rectified signals from the peak detector to convert into a direct voltage, and a comparator for comparing the direct voltage outputted from the low band pass filter with a preset reference voltage and controlling a resistance value of the active load according to the comparison result, wherein if the output direct voltage of the low band pass filter is smaller than the preset reference voltage, the comparator outputs a first control voltage for increasing the resistance value of the active load to increase gain of the differential amplifying circuit, and if the output voltage of the low band pass filter is bigger than the preset reference voltage, the comparator outputs a second control voltage for reducing the resistance value of the active load to decrease gain of the differential amplifier.

According to a preferred embodiment of the invention, the resonance circuit comprises a parallel resonance circuit including an inductor connected between the output terminals and a variable capacitor connected between the output terminals, the variable capacitor having a capacitance value varied by the control voltage.

According to another preferred embodiment of the invention, the differential amplifying circuit comprises two transistors, each having a drain connected to each of the output terminals, a gate connected to the drain and a source grounded. At this time, preferably, each of the transistors comprises an n-channel MOSFET.

According to further another preferred embodiment of the invention, the active load comprises two transistors, each having a drain connected to each of the output terminals, a source connected to a power supply and a gate, the gates of the transistors connected to each other. At this time, the control voltage of the comparator is inputted to the gates of the transistors. Preferably, each of the transistors comprises a p-channel MOSFET.

According to further another preferred embodiment of the invention, the automatic amplitude controller further comprises a reference voltage source for generating a predetermined reference voltage.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a circuit diagram illustrating a conventional voltage controlled oscillator;

FIG. 2 is a circuit diagram illustrating a voltage controlled oscillator having an automatic amplitude control function according to an embodiment of the invention.

### DETAILED DESCRIPTION OF THE PREFERRED EMBODIMENT

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

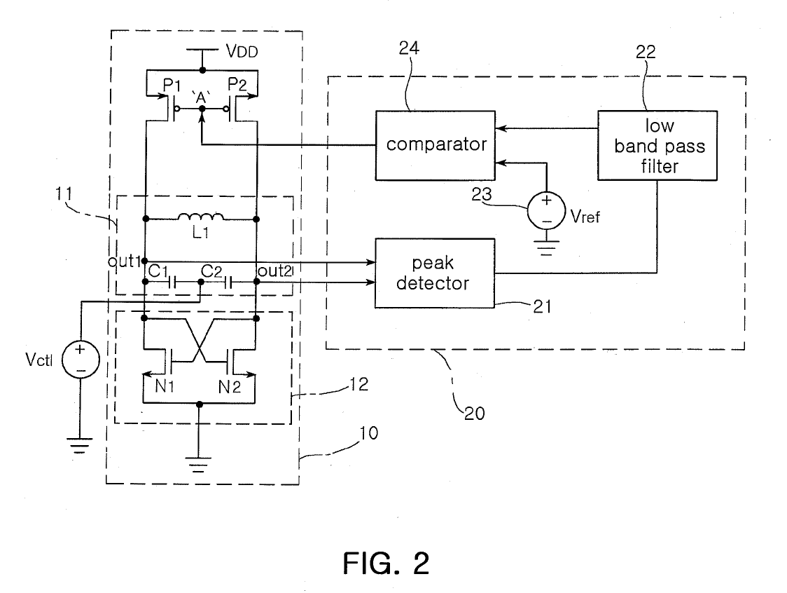

FIG. 2 is a circuit diagram illustrating a voltage controlled oscillator having an automatic amplitude control function according to an embodiment of the invention. Referring to FIG. 2, according to a preferred embodiment of the invention, the voltage controlled oscillator having the automatic amplitude control (AAC) function largely includes a voltage control oscillating part 10 and an automatic amplitude controlling part 20.

The voltage control oscillating part 10 includes a resonance circuit 11, a differential amplifying circuit 12 and active loads P1 and P2. The resonance circuit 11 generates a resonance signal with a resonance frequency determined by a control voltage V_{ctl}. The differential amplifying circuit 12 feeds back the resonance signal from the resonance circuit 11 to output two oscillation signals having a phase difference of 180° to two output terminals out1 and out2. Also, the active loads control the gain of the differential amplifying circuit 12.

More specifically, the resonance circuit 11 is a parallel resonance circuit including an inductor L1 and variable capacitors C1 and C2. The inductor L1 is connected between the output terminals out1 and out2. The variable capacitors C1 and C2 are connected between the output terminals out1 and out2, and have a capacitance varied by the control voltage V_{ctl}. The control voltage V_{ctl} may be applied to a connecting node of the serially connected variable capacitors C1 and C2.

The differential amplifying circuit 12 includes two transistors N1 and N2 each having a drain connected to each of the output terminals out1 and out2, a gain connected to the drain, and a source grounded. Preferably, the transistors N1 and N2 are configured as equal n-channel MOSFETs N1 and N2.

The active loads P1 and P2 include two transistors P1 and P2 each having a drain connected to each of the output terminals out1 and out2, a source connected to a power supply VDD, and a gate. Here, the gates of the transistors are connected to each other. A control voltage of a comparator 24 of the automatic amplitude controlling part 20 is inputted to the gates of the transistors P1 and P2, thereby adjusting a resistance value of the loads. Preferably, the transistors P1 and P2 are configured as equal p channel MOSFETs P1 and P2.

The automatic amplitude controlling part 20 includes a peak detector 21, a low band pass filter 22, and a comparator 24. The peak detector 21 receives the oscillation signals outputted from the output terminals out1 and out2 of the voltage control oscillating part 10 and detects respective peaks thereof to rectify the oscillation signals. The low band pass filter 22 receives the rectified signals from the peak detector 21 to convert into a direct voltage. The comparator 24 compares the direct voltage outputted from the low band pass filter 22 with a preset reference voltage Vref and outputs a control voltage for controlling a resistance value of the active loads P1 and P2 of the voltage control oscillating part 10 according to the comparison result.

Moreover, the automatic amplitude controlling part 20 further includes a reference voltage source 23 for generating a predetermined reference voltage Vref. The reference voltage source 23 may generate a reference voltage adjusted to a predetermined value by a user in accordance with requirements of the system.

With reference to FIG. 2, a greater detailed explanation will be given hereunder about operations of this voltage controlled oscillator having the AAC function according to the preferred embodiment of the invention.

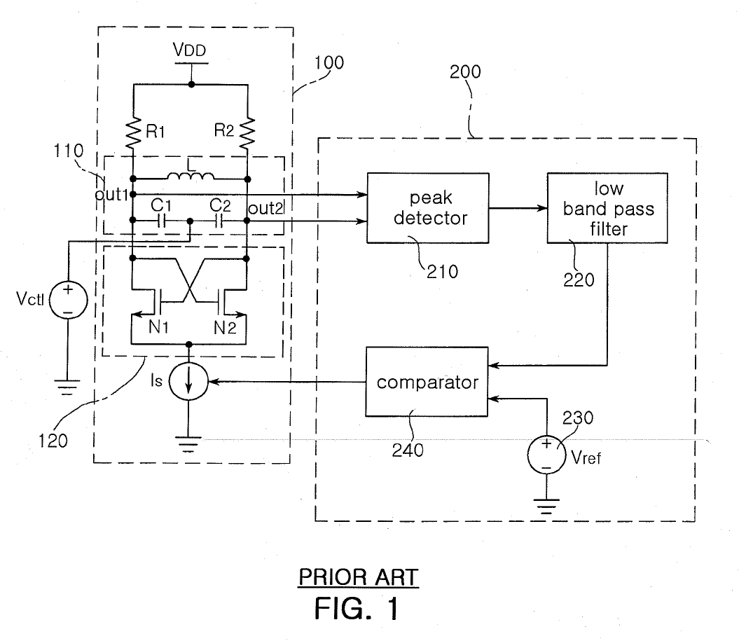

First, a control voltage V_{ctl} is applied between the capacitors C1 and C2 within the oscillation circuit 10 so that capacitance of the variable capacitors C1 and C2 is controlled to generate a resonance signal with a frequency set. Meanwhile, the differential amplifying circuit 12 has two n-channel MOSFETs N1 and N2 feeding back each other, thereby achieving differential negative resistance. Therefore, in case where the resonance signal from the oscillation circuit 10 has a frequency of f₀, each of the output terminals out1 and out2 of the differential amplitude circuit 12 (output terminals of the voltage controlled oscillating part) which yields differential negative resistance generates an oscillation signal having a frequency f₀ and a phase difference of 180°. To control the gain of the differential amplifying circuit 12, a conventional voltage controlled oscillator employs a current source (Is of FIG. 1) commonly connected to the sources of two n-channel MOSFETs. But in the invention, the gain is controlled not by the current source but by the active loads P1 and P2, which will be explained hereunder in further detail.

The oscillation signals generated thereby are inputted to the peak detector 21 of the automatic amplitude controlling part 20. The peak detector detects respective peaks of the oscillation signals and generates rectified signals made of only positive value signals. In case where an oscillation frequency outputted from the output terminals of the voltage controlled oscillating part 10 has a frequency of f₀, the rectified signals from the peak detector 21 has a frequency of 2f₀.

Then, the rectified signals having a frequency of f₀ generated from the peak detector 21 is inputted to the low band pass filter 22, thereby converted into a direct voltage of such a type that connects the peaks of the rectified signals with each other.

Thereafter, the comparator 24 compares a reference voltage Vref preset by the reference voltage source 23 with the direct voltage outputted from the low band pass filter 22, and outputs the control voltage according to the comparison result.

The control voltage outputted from the comparator 24 serves to control a resistance value of the active loads P1 and P2 of the low band pass filter 22. Controlling the resistance value of the active loads makes it possible to control the gain of the differential amplifying circuit. The gain is expressed by Equation 1 below:
Aᵥ=gₘR_{d} Equation 1,

where Av is gain, gₘ is trans-conductance, and R_{d} is resistance value of loads.

In the conventional voltage controlled oscillator having the AAC function, according to Equation 1, gain is controlled by adjusting trans-conductance gₘ. Meanwhile, in this disclosure of the invention, gain is controlled by adjusting a resistance value R_{d} of loads since the current source for controlling trans-conductance gₘ has been eliminated.

For example, in case where the direct voltage outputted from the low band pass filter 22 is smaller than the preset reference voltage R_{d}, the comparator 24 outputs a first control voltage for increasing a resistance value of the active loads to increase the gain of the oscillation signals from the differential amplifying circuit 12. In contrast, in case where the direct voltage outputted from the low band pass filter 22 is bigger than the preset reference voltage Vref, the comparator 24 outputs a second control voltage for reducing a resistance value of the active loads P1 and P2 to decrease the gain of the oscillation signals from the differential amplifying circuit 12. Such an increase and decrease in gain makes it possible to control an output swing, i.e., amplitude of the oscillation signals outputted to a desired scale. Also, proper adjustment of the reference voltage Vref leads to control of the amplitude of the oscillation signals to a desired scale.

In the embodiment of the invention, the active loads are configured into two p-channel MOSFETs each having a drain connected to each of the output terminals out1 and out2 of the voltage control oscillating part 10, a source connected to a power supply Vdd and a gate, the gates of the p-channel MOSFETs connected to each other. At this time, in case where the output direct voltage of the low band pass filter 22 is smaller than the preset reference voltage Vref, a gate voltage of the p-channel MOSFETs P1 and P2 is raised to increase the gain of the differential amplifying circuit. In case where the output direct voltage of the low band pass filter 22 is bigger than the preset reference voltage Vref, the gate voltage of the p-channel MOSFETs P1 and P2 is reduced to decrease the gain of the differential amplifying circuit.

In this fashion, the voltage controlled oscillator having the AAC function according to the invention does not employ the current source, thereby diminishing phase noises resulting from noise components induced by the current source. Also, the voltage controlled oscillator controls an output swing (amplitude of oscillation signals outputted) of the voltage control oscillator via the automatic amplitude controlling part.

As set forth above, according to certain embodiments of the invention, in place of a conventional current source employed in a voltage control oscillator, active loads are adopted to adjust a resistance value, thereby effectively controlling amplitude of oscillation signals outputted and diminishing phase noises resulting from noise components induced by the current source. In addition, according to certain embodiments of the invention, the current source is not employed so that voltage consumption caused by the current source is reduced, and thus the voltage control oscillator can be suitably used for low voltage applications.

While the present invention has been shown and described in connection with the preferred embodiments, it will be apparent to those skilled in the art that modifications and variations can be made without departing from the spirit and scope of the invention as defined by the appended claims.

What is claimed is:

1. A voltage controlled oscillator having an automatic amplitude control function, comprising:
a voltage controlled oscillating part including a resonance circuit for generating a resonance signal with a resonance frequency determined by a control voltage, a differential amplifying circuit for feeding back the resonance signal from the resonance circuit and generating two oscillation signals having a phase difference of 180° to output to two output terminals, and an active load for controlling gain of the oscillation signals generated in the differential amplifying circuit;
an automatic amplitude controlling part including a peak detector for receiving the oscillation signals and detecting respective peaks thereof to rectify the oscillation signals, a low band pass filter for receiving the rectified signals from the peak detector to convert into a direct voltage, and a comparator for comparing the direct voltage outputted from the low band pass filter with a preset reference voltage and controlling a resistance value of the active load according to the comparison result,
wherein if the output direct voltage of the low band pass filter is smaller than the preset reference voltage, the comparator outputs a first control voltage for increasing the resistance value of the active load to increase gain of the differential amplifying circuit, and if the output voltage of the low band pass filter is bigger than the preset reference voltage, the comparator outputs a second control voltage for decreasing the resistance value of the active load to reduce gain of the differential amplifier.

2. The voltage controlled oscillator according to claim 1, wherein the resonance circuit comprises a parallel resonance circuit including an inductor connected between the output terminals and a variable capacitor connected between the output terminals, the variable capacitor having a capacitance value varied by the control voltage.

3. The voltage controlled oscillator according to claim 1, wherein the differential amplifying circuit comprises two transistors, each having a drain connected to each of the output terminals, a gate connected to the drain and a source grounded.

4. The voltage controlled oscillator according to claim 3, wherein each of the transistors comprises an n-channel MOSFET.

5. The voltage controlled oscillator according to claim 1, wherein the active load comprises two transistors, each having a drain connected to each of the output terminals, a source connected to a power supply and a gate, the gates of the transistors connected to each other,
wherein the control voltage of the comparator is inputted to the gates of the transistors.

6. The voltage controlled oscillator according to claim 5, wherein each of the transistors comprises a p-channel MOSFET.

7. The voltage controlled oscillator according to claim 1, wherein the automatic amplitude controller further comprises a reference voltage source for generating a predetermined reference voltage.

8. A voltage controlled oscillator having an automatic amplitude control function, comprising:
a parallel resonance circuit including an inductor connected between two output terminals, and a variable capacitor connected between the output terminals and having a capacitance value varied by a control voltage;
a differential amplifying circuit for feeding back a resonance signal from a resonance circuit and outputting two oscillation signals having a phase difference of 180° to the output terminals, the differential amplifying circuit including two n-channel MOSFETs, each having a drain connected to each of the output terminals, a gate connected to the drain and a source grounded;
a voltage control oscillator including two p-channel MOSFETs, each having a drain connected to each of the output terminals, a source connected to a power supply and a gate, the gates of the p-channel MOSFETs connected to each other; and
a peak detector for receiving the oscillation signals and detecting respective peaks thereof to rectify the oscillation signals;
a low band pass filter for receiving the rectified signals of the peak detector to convert into a direct voltage;
an automatic amplitude controlling part for comparing the direct voltage outputted from the low band pass filter with a preset reference voltage and outputting the control voltage to gates of the two p-channel MOSFETs according to the comparison result;
wherein if the output direct voltage of the low band pass filter is smaller than the preset reference voltage, a gate voltage of the p-channel MOSFETs is increased to raise a resistance value of the p-channel MOSFETs and thereby increase gain of the oscillation signals generated in the differential amplifying circuit, and
wherein if the output direct voltage of the low band pass filter is bigger than the preset reference voltage, the gate voltage of the p-channel MOSFETs is decreased to reduce the resistance value of the p-channel MOSFETs and thereby decrease gain of the oscillation signals generated in the differential amplifying circuit.
